(19) United States
(12) Patent Application Publication
(10) Pub. No.: US 2015/0067428 A1
(43) Pub. Date: Mar. 5, 2015

(54) SYSTEM-ON-CHIP, METHOD OF MANUFACTURE THEREOF AND METHOD OF COMMUNICATING DIAGNOSTIC DATA

(71) Applicants: Stefan Singer, Vaterstetten (DE); Joseph Circello, Phoenix, AZ (US); Heinz Wrobel, Gauting (DE)

(72) Inventors: Stefan Singer, Vaterstetten (DE); Joseph Circello, Phoenix, AZ (US); Heinz Wrobel, Gauting (DE)

(73) Assignee: FREESCALE SEMICONDUCTOR, INC., Austin, TX (US)

(21) Appl. No.: 14/397,288

(22) PCT Filed: May 2, 2012
(86) PCT No.: PCT/IB2012/052180

§ 371 Date: Oct. 27, 2014

(51) Int. Cl. G01R 31/317; G01R 31/3177

(52) U.S. Cl. CPC G01R 31/31705; G01R 31/3177
USPC 714/729; 438/800

(57) ABSTRACT

A system-on-chip comprises an internal module having diagnostic functionality, and a physical communications port coupled to a first data path and arranged to support, when in use, a datagram-based communications interface for communicating with an external data communications unit. Debug logic circuitry is operably coupled to a debug interface and the internal module, the debug interface being arranged to support communication of debug data relating to the internal module. The system-on-chip also comprises configurable hardware logic circuitry configured as datagram processing logic and is arranged to support use of a datagram to communicate with the debug logic. The datagram processing logic is operably coupled to the first data path and a second data path, the second data path being operably coupled to the debug interface.

### FIELD OF THE INVENTION

This invention relates to a system-on-chip, a method of manufacturing a system-on-chip, and a method of communicating diagnostic data.

### BACKGROUND OF THE INVENTION

In the field of semiconductors, it is known to provide embedded systems with debugging capabilities in order to support diagnostic operations in relation to a given embedded system. One known technique requires the provision of a dedicated connection for debugging purposes in order to obtain data from or provide data and/or instructions to a diagnostic module of the embedded system, for example in accordance with known interface types, such as the Joint Test Action Group (JTAG) interface, the On-Chip Emulation (OnCE) interface, the Nexus 5001 interface and Background Debug Mode (BDM) interface. Some of these interfaces are standardised and many possess common features, for example use of a set of signals to carry diagnostic data and another set of “sideband” signals to obtain or manage diagnostic data correctly. For example, in the JTAG standard, the TDI, TDO and TCK signals are used to bear the diagnostic data, whereas the TRST and TMS signals, the integrated circuit specific reset or individual status signals are used to obtain or manage the diagnostic data. Support for such hardware/software interfaces in embedded systems does not require additional software. However, such interfaces have dedicated communication requirements and are not typically accessible from the exterior of the device in a final production system. Attempting to use the diagnostic functionality “in the field” can thus be cumbersome and/or uneconomic to support. In some cases, disassembly of part of a product in which the integrated circuit is embedded, for example an automobile, is required in order to gain probe access to the diagnostic module. In this regard, the disassembly can influence diagnostic results. Furthermore, these known interfaces do not support any error checking in relation to communication of diagnostic data, which devalues the reliability of the diagnostic data.

Another known technique requires the use of a so-called target-resident kernel debugger, for example a Read Only Memory (ROM) monitor or a GNU Debugger (GDB) stub. The debugger can be accessed externally from the embedded system through an available standard communications interface, for example Ethernet. However, this approach problematically requires a kernel to be installed in the embedded system, which consumes resources and cannot be debugged, i.e. a software overhead is present and so resources of the embedded system are consumed. Additionally, the kernel, or anything involved in or directly influenced by an associated debug path, cannot be debugged using the same target-resident kernel debugger technique.

### SUMMARY OF THE INVENTION

The present invention provides a system-on-chip, a method of manufacturing a system-on-chip and a method of communicating diagnostic data as described in the accompanying claims.

Specific embodiments of the invention are set forth in the dependent claims.

These and other aspects of the invention will be apparent from and elucidated with reference to the embodiments described hereinafter.

### BRIEF DESCRIPTION OF THE DRAWINGS

Further details, aspects and embodiments will be described, by way of example only, with reference to the drawings. In the drawings, like reference numbers are used to identify like or functionally similar elements. Elements in the figures are illustrated for simplicity and clarity and have not necessarily been drawn to scale.

FIG. 1 is a schematic diagram of an example of a system-on-chip device;

FIG. 2 is a schematic diagram of the system-on-chip device of FIG. 1 in greater detail;

FIG. 3 is a flow diagram of a first part of an example of a method of communicating diagnostic data using the system-on-chip device of FIG. 1;

FIG. 4 is a flow diagram of a second part of an example of the method of communicating diagnostic data using the system-on-chip device of FIG. 1;

FIG. 5 is a schematic diagram of an example of a datagram; and

FIG. 6 is a schematic diagram of an example of a payload of the datagram of FIG. 5.

### DETAILED DESCRIPTION OF THE PREFERRED EMBODIMENTS

Because the illustrated embodiments of the present invention may for the most part, be implemented using electronic components and circuits known to those skilled in the art, details will not be explained in any greater extent than that considered necessary, for the understanding and appreciation of the underlying concepts of the present invention and in order not to obfuscate or distract from the teachings of the present invention.

As used herein, the term “system on chip” (SoC) is used to refer to an integrated circuit in a single integrated circuit package, e.g. implemented on a single die or on multiple interconnected dies, which integrates several or all of the major functions of a complete working system. An SoC can e.g. be a general purpose microprocessor, a microcontroller, a digital signal processor or other type of microprocessor. An SoC can e.g. comprise one or more of the following: one or multiple processor cores, on-chip memory, additional circuitry arranged to perform analogue, digital, mixed-signal or radio frequency functions of the system, and interfacing peripheral modules to enable the SoC to communicate with the outside world. One known application for SoCs is in the field of so-called “embedded systems”.

In this respect, an embedded system is a system dedicated to a specific real time application. The embedded system comprises a combination of hardware and software. The embedded system can be of a fixed capability or programmable. The embedded system can comprise one or more SoCs.

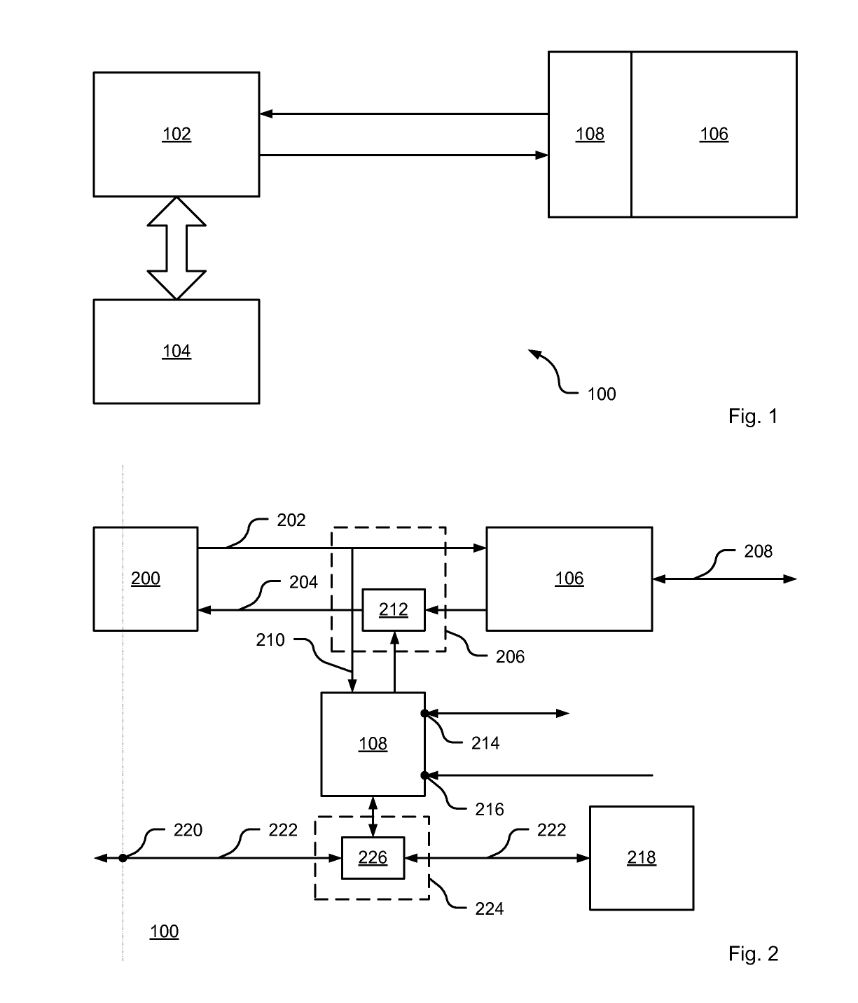

Referring to FIG. 1, an integrated circuit on a single die comprises an SoC device 100 shown herein. The SoC device 100 may comprise a debug module 102, which in this example is a dedicated logic circuit that is operably coupled to an internal module or unit 104 having diagnostic functionality supporting debugging of the module 104. The internal module 104 can be any suitable resource of the SoC device 100 that requires diagnostic support, for example a processor core or scan chain circuitry, or logic circuitry arranged to gather statistical or trace data within the SoC device 100. In this example, the debug module 102 constitutes debug logic circuitry arranged to support communication of debug data relating to the internal module 104 in accordance with a known interface, for example the Joint Test Action Group (JTAG) interface. However, any other suitable interface can be supported, for example the On-Chip Emulation (OnCE) interface, the Nexus 5001 interface and/or the Background Debug Mode (BDM) interface.

The debug logic circuitry 102 is operably coupled to an internal data communications unit 106 that supports a datagram-based communications interface, for example an Ethernet communications unit, such as a communications unit arranged to operate in accordance with the Institute of Electrical and Electronics Engineers (IEEE) 802.3 standard. The debug logic circuitry 102 is operably coupled to the internal data communications unit 106, via datagram processing logic circuitry 108 that is arranged to support use of a datagram to communicate with the debug logic circuitry.

The datagram processing logic circuitry 108 is configurable hardware logic circuitry, this being distinct from programmable hardware. The configurable logic circuitry is configurable prior to execution of the SoC device 100 in accordance with the configuration. However, it is typically not reconfigurable during operation and it is not programmable in any event. In this regard, the configurable logic circuitry differs from software in that the logic circuitry does not execute re-writable code, which constitutes the result of programming.

Turning to FIG. 2, the SoC device 100 also comprises a physical communications port 200, for example a RJ45 port; electrical signals can be applied to the internal data communications unit 106 and electrical signals can be received from the internal data communications unit 106 from/to the outside of the SoC device 100. Of course, any other suitable port type can be employed. The port 200 enables data to be communicated to the SoC device 200 from a source, for example another data communications unit, external to the SoC device 100.

To support communication of data with the internal data communications unit 106, a first data path connects the port 200 to the internal data communications unit 106. The first data path can comprise a first input path 202 and a first output path 204.

The first data path is tapped by a first tap arrangement 206 in order to couple the datagram processing logic 108 to the first data path between the port 200 and the internal data communications unit 106. The internal data communications unit 106 is also coupled to an internal bus 208 of the SoC device 100. The internal data communications unit 106 can thus communicate data received, via the internal data communications unit 106, from entities external to the SoC device 106 to other resources within the SoC device 100 that are coupled to the internal bus 208.

In this example, the first tap arrangement 206 comprises a first input path tap 210 and a first output path tap 212. The first input path tap 210 can, for example, be a wired connection. The first output path tap 212 can comprise a first multiplexer for transferring signals between the first output path 204 and the datagram processing logic circuitry 108.

The datagram processing logic circuitry 108 also comprises a first I/O port 214 for transmitting and receiving signals relating to sideband communications to obtain and/or manage diagnostic data for debugging purposes. The first I/O port may comprise a number of physical connections to different hardware blocks, the physical connections being dedicated to respective specific functions at chip design time, for example connections to a reset control block (not shown), a serialiser/deserialiser (SerDes) Phase Locked Loop (PLL) control block (not shown), a Build In Self Test (BIST) block, a temperature monitoring block (not shown), and/or a debug block (not shown). Each of these blocks is capable of transmitting so-called “sideband signal”. For example, the reset control block can generate a reset command or signal for the SoC device 100, the SerDes PLL control block can provide data relating to individual PLL lock status' from the SoC device 100, the BIST block can provide a signal indicative of the SoC device 100 being in a “healthy” state, the temperature monitoring block can provide data indicative of a so-called “panic threshold” being exceeded, and the debug block can provide a Joint Test Action Group (JTAG) Test Mode State (TMS) signal on a Test ReSeT (TRST) signal.

A second input port 216 of the datagram processing logic circuitry 108 is provided to receive a configuration signal for the datagram processing logic circuitry 108 upon powering-up of the SoC device 100. The configuration signal can, for example, comprise one or more of: information to determine whether the datagram processing logic circuitry 108 is to be enabled, a setting for a MAC address to which the datagram processing logic circuitry 108 should use, a setting for a PHY/interface mode, and/or a setting of a bit rate for the physical port 200.

The debug logic circuitry 102 also comprises debug interface 218. The debug interface 218 may be operably coupled to a traditional physical debug interface 220 via a second data path 222 and communicate with the debug logic circuitry 102 using one or more of the known debug interface protocols mentioned above.

A second tap arrangement 224 is operably coupled to the datagram processing logic 108 and the second data path 222. In this example, the second tap arrangement 224 comprises a bidirectional tap 226, for example a second multiplexer for transferring signals between the second data path 222 and the datagram processing logic 108.

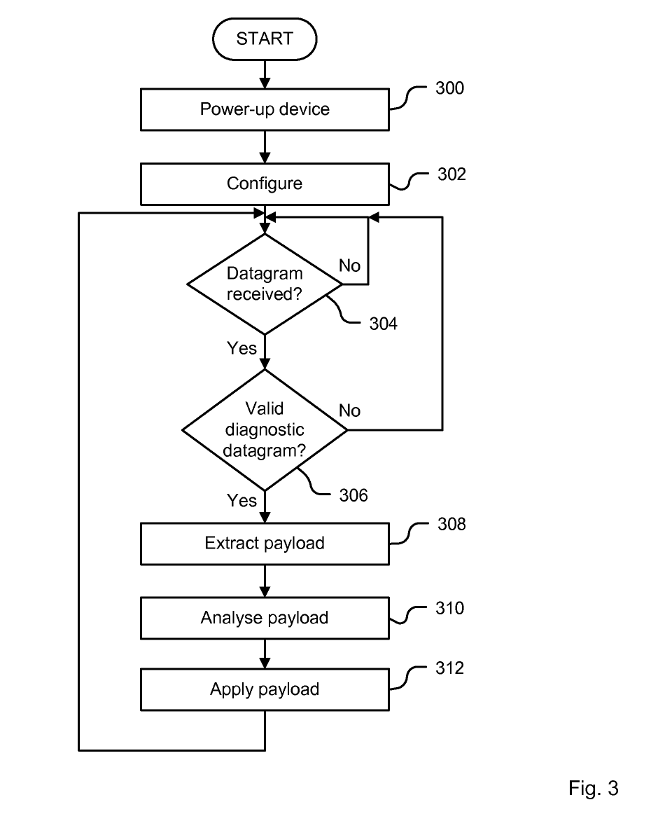

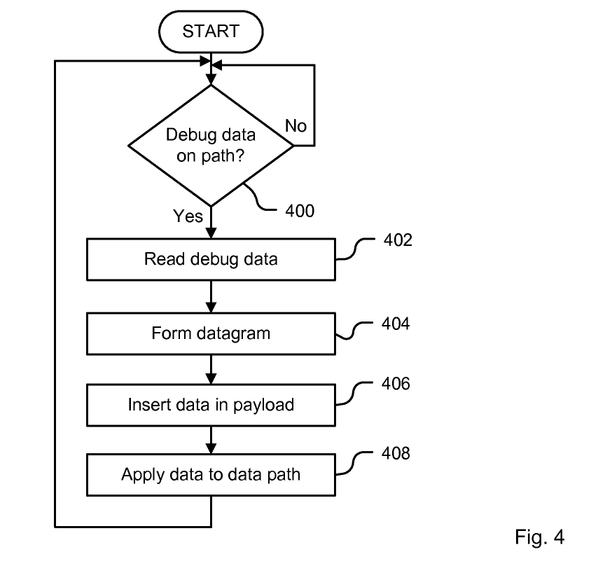

The SoC device may perform a method as illustrated in FIGS. 3 and 4, and for example operate as follows.

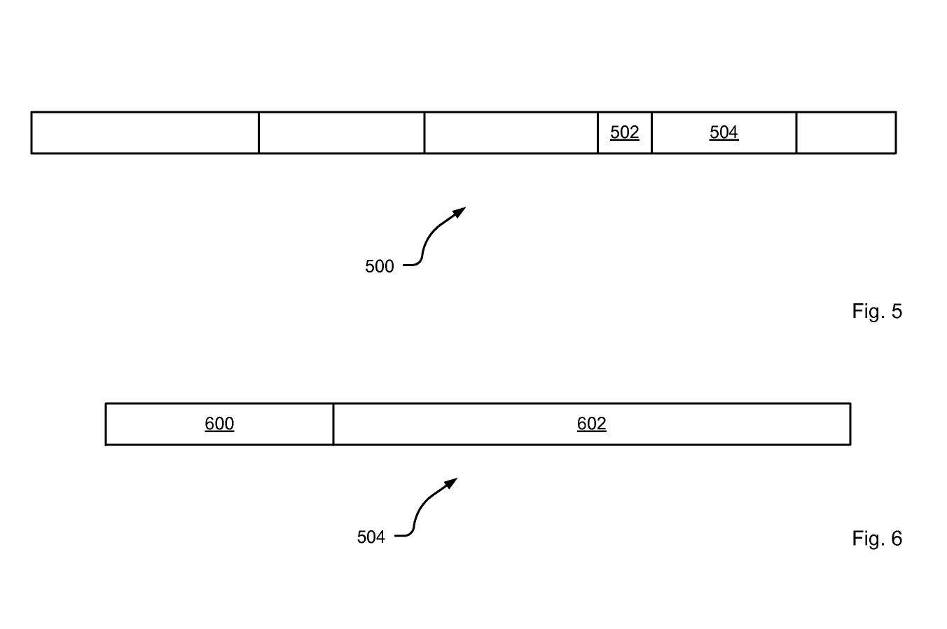

In operation (FIGS. 3 and 4), the SoC device 100 is initially powered-up (Block 300) and configuration settings are communicated (Block 302) to the datagram processing logic circuitry 108. Thereafter, the datagram processing logic circuitry 108 monitors (Block 304), via the first input path tap 210, incoming datagrams, for example a first Ethernet frame 500 (FIG. 5), received by the internal data communications unit 106 via the port 200.

The datagram processing logic circuitry 108 analyses (Block 306) a copy of the Ethernet frame 500 obtained via the first input path tap 210, and in particular an EtherType field 502 of the Ethernet frame 500, in order to determine whether the Ethernet frame 500 is a valid frame, i.e. to determine whether the datagram is tagged as containing debug data. The EtherType field 502 is, in this example, a field of the datagram comprising a data structure definition, which can be used to identify the datagram as a type bearing diagnostic or debug data not intended to form part of any regular data communications in which other resources of the SoC device 100 participate. In relation to validity of the frame, Cyclic Redundancy Check (CRC) bits and a header of the payload of the Ethernet frame 500 can also be analysed in order to determine whether or not a compliant diagnostic frame has been received.

If the datagram processing logic circuitry 108 determines that the EtherType field 502 of the Ethernet frame 500 does not bear a suitable code tagging the datagram as containing diagnostic data, then the Ethernet frame 500 is ignored by the datagram processing logic circuitry 108 as relating to a non-diagnostic communication, not of interest to the debug logic circuitry 102, and the datagram processing logic circuitry 108 continues to await (Block 304) a following datagram. If the Ethernet frame 500 is tagged as containing data relating to debugging, in this example by virtue of the EtherType field 502 being correctly completed/populated, in response to this determination the datagram processing logic circuitry 108 extracts (Block 308) a payload 504 of the Ethernet frame 500 containing debug data intended for communication to the debug logic circuitry 102. In this respect, the payload 504 conforms to a payload data structure definition comprising a header field to identify a type of debug data or command and a content field optionally comprising data relating to the type or command contained in the header field.

Additionally, in such circumstances, the internal data communications unit 106 also analyses the EtherType field 502 of the Ethernet frame 500. As the field is set to indicate that the Ethernet frame 500 contains diagnostic data, this setting will be inconsistent with normal operational uses of the Ethernet frame 500 for normal data communications involving the internal data communications unit 106. The internal data communications unit 106 then drops the Ethernet frame 500. In this respect, the internal data communications unit can be configured to process the diagnostic data in the Ethernet frame 500 by logging the diagnostic data, thereby recording information that can be used to debug the debug logic circuitry 102.

Once the payload data has been extracted (Block 308) from the Ethernet frame 500, the payload 504 is further analysed (Block 310) by the datagram processing logic circuitry 108. Referring to FIG. 6, the payload 504 has a payload data structure with a header 600, in which a command is set or a debug data type identified, and content 602, containing debug data to be used in conjunction with the command set. As such, the datagram processing logic circuitry 108 transmits (Block 312) the command and content 602 to the second data path 222 in order to be received by the debug interface logic circuitry 218, and subsequent communication to the debug logic circuitry 102. In this regard, the header 600 and the content 602 are used by the datagram processing logic circuitry 108 to arrange the debug data and any sideband signals appropriately in accordance with the protocol used by the debug interface logic circuitry 218, which can include clocking in partial or complete data streams.

For communication in the converse direction (FIG. 4), the datagram processing logic circuitry 108 monitors the second data path 222 via the second tap arrangement 224 in order to determine (Block 400) when the debug interface logic circuitry 218 is communicating data on the second data path 222 according to the specification of the debug interface logic circuitry 218. In this respect, if no sideband or diagnostic data is being transmitted by the debug interface logic circuitry 218, then the datagram processing logic circuitry 108 does not have any data to encapsulate into a datagram for communication via the port 200 and does not prepare or transmit the datagram. Alternatively, in the event that the datagram processing logic circuitry 108 detects the communication of diagnostic data by the debug interface logic circuitry 218, the datagram processing logic circuitry 108 reads (Block 402) the diagnostic data and forms (Block 404) a second datagram. For example, another Ethernet frame in which the data read via the second tap arrangement 224 is inserted (Block 406) into the payload field of the another Ethernet frame in accordance with the data structure definition of the payload 504. Also, the datagram is tagged by the datagram processing logic circuitry to indicate that it contains debug data. Once the another Ethernet frame has been formed, and the formed payload data encapsulated therein, the datagram processing logic circuitry 108 is applied to the first data path by the datagram processing logic circuitry 108 via the first tap arrangement 206. The another Ethernet frame, and hence the diagnostic data contained therein, are therefore transmitted to, and can be received by, a communications device external to the SoC device 100 for analysis.

Hence, datagrams can be employed to communicate diagnostic data compliant with a first interface standard internal to the SoC device 100 by encapsulating the diagnostic data in a datagram compliant with another communications protocol and communicate the datagram with diagnostic devices external to the SoC device 100.

It is thus possible to provide a system-on-chip and a method of communicating diagnostic data capable of re-using an existing communications interface for debugging of an embedded system. Also, the use of target-specific debug kernels or other so-called “target-side” CPU intervention can be avoided. Thus, the system on chip and method can provide an inexpensive way to diagnose problems with microcontroller devices as well as to program microcontroller and/or microprocessor devices, for instance by a user of the embedded systems without the need for any specialist equipment. Also, by use of the EtherType field in an Ethernet frame debug-related data can be communicated without “breaking” or contravening the Ethernet standard. The datagram processing logic circuitry 108 is reconfigurable from a device external to the SoC device 100 and can also be ready for use very quickly, for example immediately after powering-up the SoC device 100.

Of course, the above advantages are exemplary, and these or other advantages may be achieved by the invention. Further, the skilled person will appreciate that not all advantages stated above are necessarily achieved by embodiments described herein.

In the foregoing specification, the invention has been described with reference to specific examples of embodiments of the invention. It will, however, be evident that various modifications and changes may be made therein without departing from the broader scope of the invention as set forth in the appended claims and that the claims are not limited to the described examples. For example, instead of the multiplexers described herein, the first and second taps 206, 224 may be implemented using simple wired-OR connections or logic circuitry, or the first and second taps 206, 224 can be absent if the physical port 200 is to be dedicated to diagnostic communication and/or there is no need for a traditional diagnostic interface via the traditional physical port 200 and the second data path 222.

As another example, although the datagram processing logic circuitry 106 operates in relation to Layer 2 of the Open Systems Interconnection (OSI) model, the datagram processing logic circuitry 106 may also support communications in relation to another layer, for example Layer 3 of the OSI model, i.e. Internet Protocol. In a further example, the datagram processing logic circuitry 106 can implement a security protocol, by way of a suitable mechanism that ensures that the datagrams are not used in a malicious manner to interfere with or corrupt use of the SoC device 100 through misuse or unauthorised use of datagrams relating to diagnostic data. Also, the above embodiments describe the allocation of a MAC address to the datagram processing logic circuitry 106, and the SoC device 100 can comprise multiple datagram processing logic units and with separate MAC addresses allocated to each datagram processing logic circuitry. However, in the alternative, multiple EtherType codes can be allocated for debug purposes, thereby enabling one MAC address to be used in combination with multiple EtherType codes to identify different datagram processing logic units. Also, a combination can be employed, whereby multiple MAC addresses are allocated and at least one of the allocated MAC address is used in combination with EtherType codes to identify individual datagram processing logic circuitry for communications purposes.

For example, although FIGS. 1 and 2 and the discussions thereof describe an example information processing architecture, this example architecture is presented merely to provide a useful reference in discussing various aspects of the invention. Of course, the description of the architecture has been simplified for purposes of discussion, and the device may be implemented with any suitable information processing architecture. Those skilled in the art will recognise that the boundaries between blocks are merely illustrative, and that alternative embodiments may merge blocks or circuit elements or impose an alternate decomposition of functionality upon various logic blocks or circuit elements.

Thus, it is to be understood that the architectures depicted herein are merely exemplary, and that in fact many other architectures can be implemented which achieve the same functionality. In an abstract, but still definite sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Also for example, in one embodiment, the illustrated elements of the system-on-chip device 100 are circuitry located on a single integrated circuit or within a same device. Alternatively, the system-on-chip device 100 may include any number of separate integrated circuits or separate devices interconnected with each other. For example, the internal data communications unit 106 may be located on a same integrated circuit as the debug interface logic circuitry 218 or on a separate integrated circuit or located within another device, peripheral or slave discretely separate from other elements of system-on-chip device 100.

Furthermore, those skilled in the art will recognize that boundaries between the functionality of the above described operations are merely illustrative. The functionality of multiple operations may be combined into a single operation, and/or the functionality of a single operation may be distributed in additional operations. Moreover, alternative embodiments may include multiple instances of a particular operation, and the order of operations may be altered in various other embodiments.

The examples set forth herein, or portions thereof, may be implemented as soft or code representations of physical circuitry or of logical representations convertible into physical circuitry, such as in a hardware description language of any appropriate type.

Also, the invention is not limited to physical devices or units implemented in non-programmable hardware but can also be applied in programmable devices or units able to perform the desired device functions by operating in accordance with suitable program code, such as mainframes, minicomputers, servers, workstations, personal computers, notepads, personal digital assistants, electronic games, automotive and other embedded systems, cell phones and various other wireless devices, commonly denoted in this application as ‘computer systems’.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements The mere fact that certain measures are recited in mutually different claims does not indicate that a combination of these measures cannot be used to advantage.

1. A system-on-chip, comprising:
an internal module having diagnostic functionality;
a physical communications port operably coupled to a first data path and arranged to support, when in use, a datagram-based communications interface for communicating with an external data communications unit;
debug logic circuitry operably coupled to a debug interface and the internal module, the debug interface being arranged to support communication of debug data relating to the internal module;
configurable hardware logic circuitry configured as datagram processing logic circuitry and arranged to support use of a datagram to communicate with the debug logic, the datagram processing logic circuitry being operably coupled to the first data path; and
a second data path, the second data path being operably coupled to the debug interface.

2. A system-on-chip as claimed in claim 1, wherein the datagram processing logic circuitry is arranged to obtain a copy of a first datagram and determine whether the first datagram is tagged as containing first debug data.

3. A system-on-chip as claimed in claim 2, wherein the datagram processing logic circuitry is arranged to determine whether the first datagram is tagged as containing first debug data by analysing a field of the copy first datagram provided in accordance with a data structure definition to tag the first datagram as containing the first debug data.

4. A system-on-chip as claimed in claim 2 or claim 3, wherein the copy first datagram comprises a payload, and the datagram processing logic circuitry is arranged to extract the payload from the copy first datagram in response to the datagram processing logic circuitry determining that the copy first datagram is tagged as containing first debug data.

5. A system-on-chip as claimed in claim 4, wherein the datagram processing logic circuitry is arranged to communicate at least part of the payload extracted to the debug logic circuitry via the second data path.

6. A system-on-chip as claimed in claim 1, wherein the datagram processing logic circuitry is arranged to obtain second debug data communicated by the debug interface logic circuitry and arrange the second debug data in accordance with a payload data structure definition.

7. A system-on-chip as claimed in claim 6, wherein the arranged second debug data constitutes payload data, the datagram processing logic circuitry being arranged to encapsulate the payload data as a second datagram.

8. A system-on-chip as claimed in claim 7, wherein the datagram processing logic circuitry is arranged to tag the second datagram as containing the debug data.

9. A system-on-chip as claimed in claim 7, wherein the datagram processing logic circuitry is arranged to apply the second datagram to the first data path.

10. A system-on-chip as claimed in claim 1 further comprising:
an internal data communications unit operably coupled to the physical communications port by the first data path; wherein
the datagram processing logic circuitry is operably coupled to the first data path via a first tap.

11. A system-on-chip as claimed in claim 1, wherein the datagram processing logic circuitry is operably coupled to the second data path via a second tap.

12. A system-on-chip as claimed in claim 7, wherein the payload data structure definition comprises a header field to identify a type of debug data contained within the second datagram.

13. A system-on-chip as claimed in claim 4, wherein the payload of the first datagram conforms to a payload data structure definition comprising a header field to identify a type of debug data or command and a content field optionally comprising data relating to the type or command contained in the header field.

14. A system-on-chip as claimed in claim 1, wherein the internal module is a core or processor.

15. A system-on-chip as claimed in any one of claim 1, wherein the internal module is scan chain logic circuitry.

16. A system-on-chip as claimed in claim 1, wherein the datagram processing logic circuitry supports a security protocol to prevent misuse of datagrams.

17. A system-on-chip as claimed in claim 1, wherein the datagram processing logic circuitry is arranged to receive configuration data in order to allocate a Media Access Control address thereto.

18. A method of communicating diagnostic data with debug logic circuitry of a system-on-chip, the method comprising:
configuring configurable hardware logic circuitry on the system-on-chip as datagram processing logic circuitry;
interfacing the datagram processing logic circuitry with an internal data communications unit of the system-on-chip and the debug logic circuitry via debug interface logic circuitry; and
using the datagram processing logic circuitry to use a datagram to communicate with the debug logic circuitry in order to communicate debug data concerning an internal resource of the system-on-chip having diagnostic functionality.

19. A method of manufacturing a system-on-chip, the method comprising:
providing the following elements:
an internal module having diagnostic functionality;
an internal data communications unit operably coupled to a physical communications port via a first data path and arranged to support, when in use, a datagram-based communications interface for communicating with an external data communications unit;
debug logic circuitry operably coupled to a debug interface and the internal module, the debug interface being arranged to support communication of debug data relating to the internal module;
configuring configurable hardware logic circuitry as datagram processing logic circuitry to support, when in use, use of a datagram to communicate with the debug logic circuitry;
coupling a first tap to the first communications path;
coupling a second tap to a second data path, the second data path being operably coupled to the debug interface; and
manufacturing an integrated circuit comprising the above elements.

20. A product comprising an embedded electronic system with a system-on-chip as claimed in claim 1.
